(19) United States
(12) Patent Application Publication
(10) Pub. No.: US 2013/0337641 A1
(43) Pub. Date: Dec. 19, 2013

(54) PLASMA DOPING METHOD AND APPARATUS

(71) Applicant: Panasonic Corporation, (US)

(72) Inventors: Tomohiro OKUMURA, Osaka (JP); Yuichiro SASAKI, Osaka (JP); Katsumi OKASHITA, Aichi (JP); Hiroyuki ITO, Chiba (JP); Bunji MIZUNO, Nara (JP)

(21) Appl. No.: 13/864,977

(22) Filed: Apr. 17, 2013

Related U.S. Application Data
(62) Division of application No. 13/108,625, filed on May 16, 2011, now abandoned.
Application No. 13/108,625 is a division of application No. 12/137,897, filed on Jun. 12, 2008, now abandoned.
Application No. 12/137,897 is a continuation of application No. PCT/JP2007/069287, filed on Oct. 2, 2007.

(30) Foreign Application Priority Data
Oct. 3, 2006 (JP) 2006-271605

(51) Int. Cl. H01L 21/265; H01L 21/223

(52) U.S. Cl. CPC H01L 21/26513; H01L 21/2236
USPC 438/513

(57) ABSTRACT

A plasma doping method and an apparatus which have excellent reproducibility of the concentration of impurities implanted into the surfaces of samples. In a vacuum container, in a state where gas is ejected toward a substrate on a sample electrode through gas ejection holes provided in a counter electrode, gas is exhausted from the vacuum container through a turbo molecular pump as an exhaust device, and the inside of the vacuum container is maintained at a predetermined pressure through a pressure adjustment valve, the distance between the counter electrode and the sample electrode is set sufficiently small with respect to the area of the counter electrode to prevent plasma from being diffused outward, and capacitive-coupled plasma is generated between the counter electrode and the sample electrode to perform plasma doping. The gas used herein is a gas with a low concentration which contains impurities such as diborane or phosphine.

This application is a Divisional of U.S. application Ser. No. 13/108,625, filed May 16, 2011, which is a Divisional of U.S. application Ser. No. 12/137,897, filed Jun. 12, 2008, which is a continuation application of International Application No. PCT/JP2007/069287, filed Oct. 2, 2007, claiming priority of Japanese Patent Application No. 2006-271605, filed on Oct. 3, 2006, the entire contents of each of which are hereby incorporated by reference.

### BACKGROUND OF THE INVENTION

The present invention relates to a plasma doping method and apparatus for implanting impurities into the surfaces of samples.

For example, in fabrication of a MOS transistor, a thin oxide film is formed on the surface of a silicon substrate as a sample, and then a gate electrode is formed on the sample using a CVD apparatus or the like. Thereafter, impurities are implanted thereto by a plasma doping method as described above, using the gate electrode as a mask. By implanting impurities, for example, a metal wiring layer is formed on the sample where source and drain areas are formed in the sample to provide a MOS transistor.

As a technique for implanting impurities into the surface of a solid sample, there has been known a plasma doping method for implanting ionized impurities into a solid with low energy (refer to Patent Document 1, for example). FIG. 5 illustrates the schematic structure of a plasma processing apparatus for use in the plasma doping method as a conventional impurity implantation method described in the aforementioned Patent Document 1. In FIG. 5, there is provided a sample electrode 106 for placing thereon a sample 107 formed of a silicon substrate, in a vacuum container 101. Within the vacuum container 101, there are provided a gas supply device 102 for supplying a doping material gas containing desired elements, such as B₂H₆, and a pump 108 for decreasing the pressure within the vacuum container 101, which enables maintaining the inside of the vacuum container 101 at a predetermined pressure. A microwave waveguide 121 radiates a microwave into the vacuum container 101 through a quarts plate 122 as a dielectric window. Through the interaction of the microwave and the DC magnetic field produced by an electromagnet 123, there is formed a magnetic-field microwave plasma (electron cyclotron resonance plasma) 124 within the vacuum container 101. A high-frequency power supply 112 is connected to the sample electrode 106 through a capacitor 125, which enables controlling the potential of the sample electrode 106. Further, the conventional distance between the electrode and the quarts plate 122 is in the range of 200 to 300 mm.

In the plasma processing apparatus having such a structure, the introduced doping material gas, such as B₂H₆, is changed into plasma by the plasma generating means constituted by the microwave waveguide 121 and the electromagnet 123, and boron ions in the plasma 124 are implanted into the surface of the sample 107 by the high-frequency power supply 112.

As aspects of the plasma processing apparatus for use in plasma doping, there are known one which uses a helicon-wave plasma source (refer to Patent Document 2, for example), one which uses an inductively-coupled plasma source (refer to Patent Document 3, for example), and one which uses a parallel-plate plasma source (refer to Patent Document 4, for example), as well as the aforementioned apparatus which uses an electron cyclotron resonance plasma source.
Patent Document 1: U.S. Pat. No. 4,912,065
Patent Document 2: Japanese Unexamined Patent Publication No. 2002-170782
Patent Document 3: Japanese Unexamined Patent Publication No. 2004-47695
Patent Document 4: Published Japanese translation of PCT International Publication for Patent Application, No. 2002-522899

However, these conventional methods have an issue of poor reproducibility of the amount of implanted impurities (the amount of dose).

The present inventors have found, from various experiments, that the poor reproducibility is caused by the increase in the density of boron-based radicals within plasma. As plasma doping processing is successively performed, a thin film containing boron (boron-based thin film) is gradually deposited on the inner wall surface of the vacuum container. It is considered that, in a case of using B₂H₆ as the doping material gas, along with the increase in the thickness of the deposited film, the probability of adsorption of boron-based radicals to the inner wall surface of the vacuum container is gradually decreased, and accordingly, the density of boron-based radicals in plasma is gradually increased. Further, ions within plasma are accelerated by the potential difference between the plasma and the inner wall of the vacuum container and then impinge on the boron-based thin film deposited on the inner wall surface of the vacuum container, thereby causing sputtering. The sputtering thus caused gradually increases the amount of particles containing boron which are supplied into the plasma. Consequently, the amount of dose is gradually increased. The degree of the increase is significantly large, and after plasma doping processing is repeatedly carried out several hundreds of times, the amount of dose has been increased to about 3.3 to 6.7 times the amount of dose that is implanted in plasma doping processing performed just after the cleaning of the inner wall of the vacuum container with water and an organic solvent.

Along with the generation of plasma and stoppage thereof, the temperature of the inner wall surface of the vacuum container is varied, which also changes the probability of adsorption of boron-based radicals to the inner wall surface. This also causes the change in the amount of dose.

The present invention is made in view of the aforementioned issues in the prior art, and an object of the present invention is to provide a plasma doping method and apparatus which are capable of controlling the amount of impurities implanted to sample surfaces with higher accuracy and providing highly reproducible impurity concentration.

### SUMMARY OF THE INVENTION

In accomplishing these and other aspects, according to a first aspect of the present invention, there is provided a plasma doping method comprising:

placing a sample on a sample electrode within a vacuum container;

supplying an electric power to the sample electrode, while supplying a plasma doping gas into the vacuum container, exhausting gas from the vacuum container, and controlling an inside of the vacuum container to a plasma doping pressure, and generating plasma between a surface of the sample and a surface of a counter electrode within the vacuum container; and

performing plasma doping processing to implant impurities into the surface of the sample, in a state where a following equation (1) is satisfied, where S is an area of the surface which is faced to the counter electrode, out of surfaces of the sample, and G is a distance between the sample electrode and the counter electrode.

0.1\sqrt{(S/π)} [symbol] G [symbol] 0.4\sqrt{(S/π)} (1)

With this structure, it is possible to realize the plasma doping method having excellent reproducibility of the concentration of impurities implanted to the surfaces of samples.

According to a second aspect of the present invention, there is provided the plasma doping method as defined in the first aspect, wherein a high-frequency electric power is supplied to the counter electrode which is placed opposite the sample electrode.

With this structure, it is possible to prevent the adsorption of generated plasma to the counter electrode.

According to a third aspect of the present invention, there is provided the plasma doping method as defined in the second aspect, wherein, after the sample is placed on the sample electrode within the vacuum container and before the electric power is supplied to the sample electrode,

a high-frequency electric power is supplied to the counter electrode while a pressure within the vacuum container is maintained at a plasma generating pressure which is higher than the plasma doping pressure, to generate plasma between the surface of the sample and the surface of the counter electrode within the vacuum container, gradually decreasing a pressure within the vacuum container to the plasma doping pressure after the plasma is generated, and supplying the electric power to the sample electrode after the pressure within the vacuum container reaches the plasma doping pressure.

According to a fourth aspect of the present invention, there is provided the plasma doping method as defined in the second aspect, wherein, after the sample is placed on the sample electrode within the vacuum container and before the electric power is supplied to the sample electrode,

supplying a plasma generating gas which causes discharge at a lower pressure more easily than a dilution gas used for diluting an impurity material gas in the plasma doping gas into the vacuum container, supplying the high-frequency electric power to the counter electrode while the pressure within the vacuum container is maintained at the plasma doping pressure, generating plasma between the surface of the sample and the surface of the counter electrode within the vacuum container, switching a gas supplied into the vacuum container to the plasma doping gas after the plasma is generated, and supplying the electric power to the sample electrode after the gas inside the vacuum container has been switched to the plasma doping gas.

According to a fifth aspect of the present invention, there is provided the plasma doping method as defined in the second aspect, wherein, after the sample is placed on the sample electrode within the vacuum container and before the electric power is supplied to the sample electrode,

relatively moving the sample electrode and the counter electrode to separate the sample electrode from the counter electrode such that a distance G between the sample electrode and the counter electrode is larger than a range defined by the equation (1), and in this state, supplying the high-frequency electric power to the counter electrode while a plasma doping gas is supplied into the vacuum container, gas is exhausted from the vacuum container, and the inside of the vacuum container is controlled to the plasma doping pressure, generating plasma between the surface of the sample and the surface of the counter electrode within the vacuum container, relatively moving the sample electrode and the counter electrode after the plasma is generated to restore a state where the distance G satisfies the equation (1), and thereafter, supplying the electric power to the sample electrode.

According to a sixth aspect of the present invention, there is provided the plasma doping method as defined in any one of the first to fifth aspects, wherein a concentration of impurity material gas within the gas introduced into the vacuum container is equal to or less than 1%.

According to a seventh aspect of the present invention, there is provided the plasma doping method as defined in any one of the first to fifth aspects, wherein a concentration of impurity material gas within the gas introduced into the vacuum container is equal to or less than 0.1%.

According to an eighth aspect of the present invention, there is provided the plasma doping method as defined in any one of the first to seventh aspects, wherein the gas introduced to the vacuum container is a mixed gas prepared by diluting an impurity material gas with a rare gas. Further, as defined in a ninth aspect of the present invention, there is provided the plasma doping method as defined in the eighth aspect, wherein the rare gas is He.

With this structure, it is possible to realize the plasma doping method with excellent reproducibility while realizing both accurate control of the amount of dose and a low sputtering property.

According to tenth and eleventh aspects of the present invention, there is provided the plasma doping method as defined in any one of the first to ninth aspects, wherein the impurity material gas within the gas is BxHy (x and y are positive integers) or PxHy (x and y are positive integers).

With this structure, it is possible to prevent implantation of undesirable impurities into the surfaces of samples.

According to a twelfth aspect of the present invention, there is provided the plasma doping method as defined in any one of the first to eleventh aspects, wherein the plasma doping processing is performed while the gas is ejected toward the surface of the sample through gas ejection holes provided in the counter electrode.

With this structure, it is possible to realize the plasma doping method with more excellent reproducibility of the concentration of impurities implanted to the sample surface.

Further, according to a thirteenth aspect of the present invention, there is provided the plasma doping method as defined in any one of the first to twelfth aspects, wherein the plasma doping processing is performed in a state where the surface of the counter electrode is made of silicon or a silicon oxide.

With this structure, it is possible to prevent implantation of undesirable impurities into the surfaces of samples.

According to a fourteenth aspect of the present invention, there is provided the plasma doping method as defined in any one of the first to thirteenth aspects, wherein the plasma doping processing is performed in a state where the sample is a semiconductor substrate made of silicon. According to a fifteenth aspect of the present invention, there is provided the plasma doping method as defined in any one of the first to fourteenth aspects, wherein impurities in the impurity gas contained in the gas is arsenic, phosphorus, or boron.

As the impurities, it is also possible to employ aluminum or antimony.

According to a sixteenth aspect of the present invention, there is provided a plasma doping apparatus comprising:

a vacuum container;

a sample electrode placed within the vacuum container;

a gas supply device for supplying gas into the vacuum container;

a counter electrode which is faced substantially in parallel to the sample electrode;

an exhaust device for exhausting gas from the vacuum container;

a pressure control device for controlling a pressure within the vacuum container; and

a power supply for supplying an electric power to the sample electrode, wherein

a following equation (2) is satisfied, where S is an area of a surface of the sample electrode, the surface being faced to the counter electrode and also being a placement region of the surface in which the sample is placed, and G is a distance between the sample electrode and the counter electrode.

0.1\sqrt{(S/π)} [symbol] G [symbol] 0.4\sqrt{(S/π)} (2)

With this structure, it is possible to realize the plasma doping apparatus with excellent reproducibility of the concentration of impurities implanted to the surfaces of samples.

According to a seventeenth aspect of the present invention, there is provided the plasma doping apparatus as defined in the sixteenth aspect, further comprising a high-frequency power supply for supplying a high-frequency electric power to the counter electrode.

With this structure, it is possible to prevent the adsorption of generated plasma to the counter electrode.

According to an eighteenth aspect of the present invention, there is provided the plasma doping apparatus as defined in the seventeenth aspect, wherein the pressure control device is capable of controlling the pressure within the vacuum container in such a way as to switch between a plasma doping pressure and a plasma generating pressure higher than the plasma doping pressure,

after the sample is placed on the sample electrode within the vacuum container and before the electric power is supplied to the sample electrode, the high-frequency electric power is supplied from the high-frequency power supply to the counter electrode while the pressure within the vacuum container is maintained at the plasma generating pressure which is higher than the plasma doping pressure by the pressure control device, to generate plasma between the surface of the sample and a surface of the counter electrode within the vacuum container, after the plasma is generated, the pressure within the vacuum container is gradually decreased to the plasma doping pressure by the pressure control device, and after the pressure within the vacuum container reaches the plasma doping pressure, the electric power is supplied from the power supply to the sample electrode.

According to a nineteenth aspect of the present invention, there is provided the plasma doping apparatus as defined in the seventeenth aspect, wherein the gas supply device is capable of supplying the plasma doping gas and plasma generating gas which causes discharge at a lower pressure more easily than a dilution gas used for diluting an impurity material gas in the plasma doping gas, in a switchable manner,

after the sample is placed on the sample electrode within the vacuum container and before the electric power is supplied to the sample electrode, the plasma generating gas which causes discharge at a lower pressure more easily than the dilution gas used for diluting the impurity material gas in the plasma doping gas is supplied into the vacuum container by the gas supply device, and the high-frequency electric power is supplied from the high-frequency power supply to the counter electrode while the pressure within the vacuum container is maintained at a plasma doping pressure by the pressure control device, to generate plasma between the surface of the sample and the surface of the counter electrode within the vacuum container, after the plasma is generated, the gas supplied into the vacuum container is switched to the plasma doping gas, and after the gas inside the vacuum container has been switched to the plasma doping gas, the electric power is supplied to the sample electrode.

According to a twentieth aspect of the present invention, there is provided the plasma doping apparatus as defined in the seventeenth aspect, further comprising a distance-adjustment driving device for relatively moving the sample electrode with respect to the counter electrode,

after the sample is placed on the sample electrode within the vacuum container and before the electric power is supplied to the sample electrode, the sample electrode and the counter electrode are moved relative to each other, by the distance-adjustment driving device, to separate the sample electrode from the counter electrode such that the distance G between the sample electrode and the counter electrode is larger than a range defined by the equation (2), and in this state, the high-frequency electric power is supplied from the high-frequency power supply to the counter electrode while a plasma doping gas is supplied into the vacuum container, gas is exhausted from the vacuum container, and the inside of the vacuum container is controlled to a plasma doping pressure to generate plasma between the surface of the sample and the surface of the counter electrode within the vacuum container, after the plasma is generated, the sample electrode and the counter electrode are moved relative to each other by the distance-adjustment driving device to restore a state where the distance G satisfies the equation (2), and thereafter, the electric power is supplied to the sample electrode.

According to a twenty-first aspect of the present invention, there is provided the plasma doping apparatus as defined in any one of the sixteenth to twentieth aspects, wherein the gas supply device is adapted to supply the gas through gas ejection holes provided in the counter electrode.

With this structure, it is possible to realize the plasma doping apparatus with more excellent reproducibility of the concentration of impurities implanted to the surfaces of samples.

Further, according to a twenty-second aspect of the present invention, there is provided the plasma doping apparatus as defined in any one of the sixteenth to twenty-first aspects, wherein the surface of the counter electrode is made of silicon or a silicon oxide.

With this structure, it is possible to prevent implantation of undesirable impurities into the surfaces of samples.

According to a twenty-third aspect of the present invention, there is provided a plasma doping method comprising:

placing a sample on a sample electrode within a vacuum container;

relatively moving the sample electrode and the counter electrode to separate the sample electrode from the counter electrode such that a distance G between the sample electrode and the counter electrode opposite the sample electrode is larger than a distance for plasma doping processing, and in this state, supplying the high-frequency electric power to the counter electrode while supplying a plasma doping gas into the vacuum container, exhausting a gas from the vacuum container, and controlling an inside of the vacuum container to a plasma doping pressure, to generate plasma between a surface of the sample and a surface of the counter electrode within the vacuum container;

after the plasma is generated, relatively moving the sample electrode and the counter electrode to restore the distance G to a distance for plasma doping processing, and thereafter, supplying the electric power to the sample electrode; and

performing plasma doping processing to implant impurities into the surface of the sample, in a state where the distance G between the sample electrode and the counter electrode is maintained at the distance for plasma doping processing, where S is an area of the surface which is faced to the counter electrode, out of surfaces of the sample.

### BRIEF DESCRIPTION OF DRAWINGS

These and other aspects and features of the present invention will become clear from the following description taken in conjunction with the preferred embodiments thereof with reference to the accompanying drawings, in which:

FIG. 1A is a cross-sectional view illustrating the structure of a plasma doping apparatus for use in a first embodiment of the present invention;

FIG. 1B is an enlarged cross-sectional view illustrating the structure of a sample electrode in the plasma doping apparatus for use in the first embodiment of the present invention;

FIG. 2 is a graph illustrating comparison between the relationship between the number of processed substrates and the surface resistance according to the first embodiment of the present invention and such a relationship in the prior art;

FIG. 3 is a cross-sectional view illustrating the structure of a plasma doping apparatus for use in a modification of the first embodiment of the present invention;

FIG. 4 is a cross-sectional view illustrating the structure of a plasma doping apparatus for use in another modification of the first embodiment of the present invention; and

FIG. 5 is a cross-sectional view illustrating the structure of a plasma doping apparatus used in a conventional example.

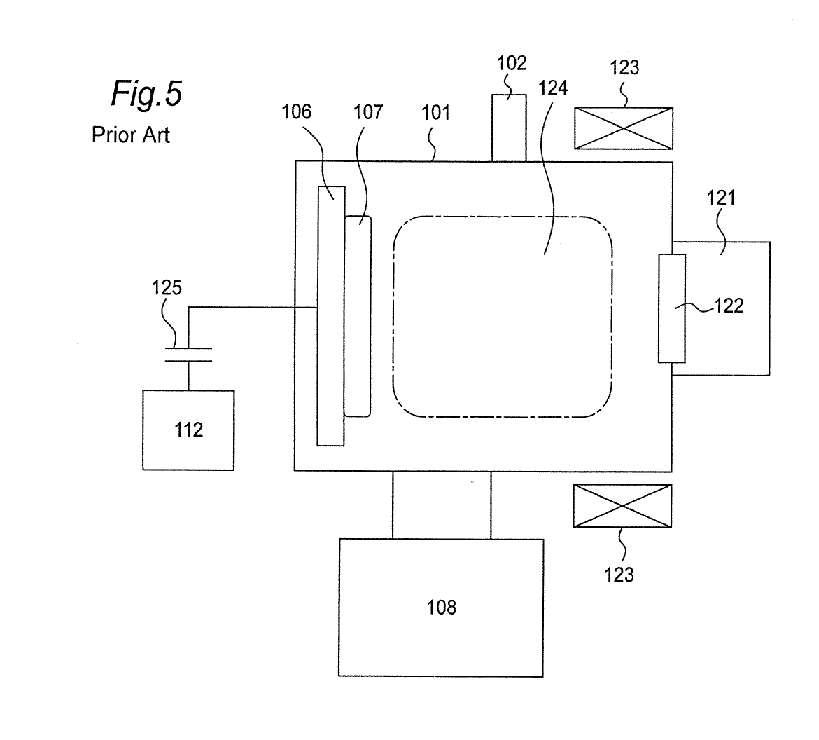

### DETAILED DESCRIPTION OF THE PREFERRED EMBODIMENTS

Before the description of the present invention proceeds, it is to be noted that like parts are designated by like reference numerals throughout the accompanying drawings.

Hereinafter, embodiments of the present invention will be described in detail, with reference to the drawings.

### First Embodiment

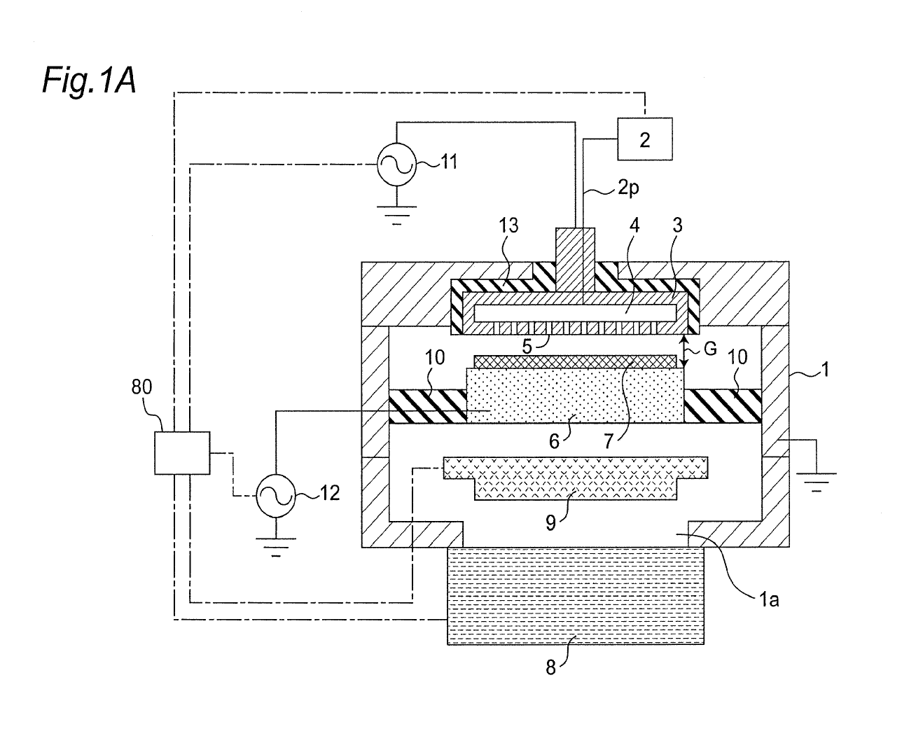

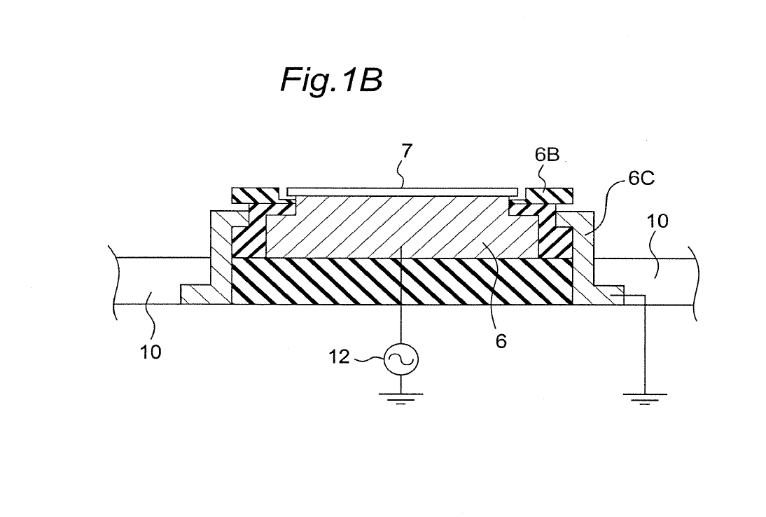

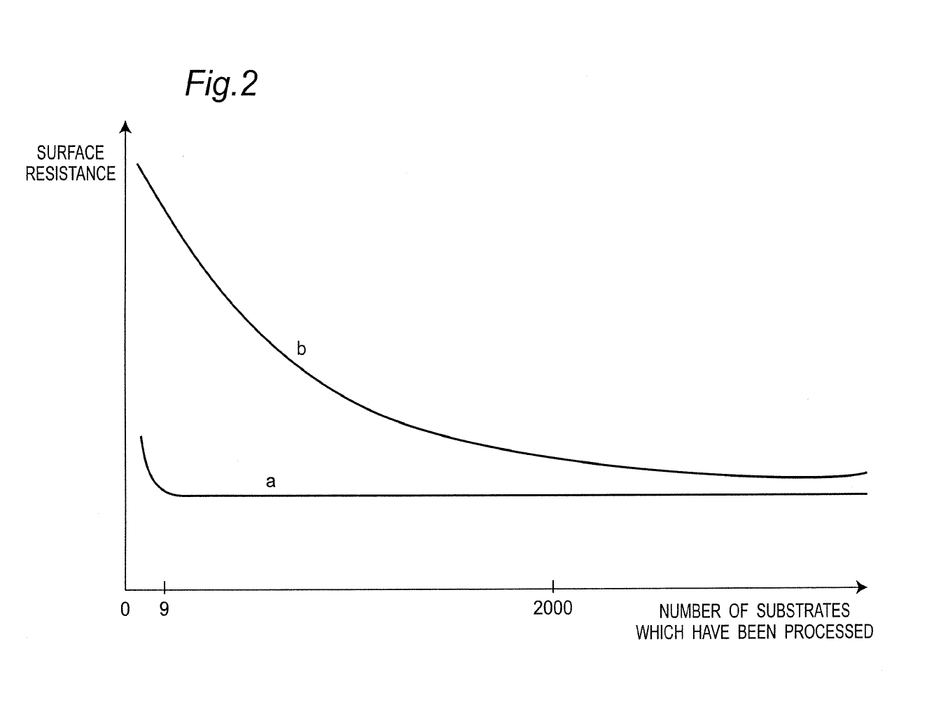

Hereinafter, a first embodiment of the present invention will be described with reference to FIGS. 1A to 2.

A plasma doping apparatus according to the first embodiment of the present invention is a plasma doping apparatus including a vacuum container (vacuum chamber) 1, a sample electrode (first electrode) 6 placed within the vacuum container 1, a gas supply device 2 for supplying plasma doping gas into the vacuum container 1, a counter electrode (second electrode) 3 which is placed within the vacuum container 1 and is opposed substantially in parallel to the sample electrode 6, a turbo pump 8 serving as one example of an exhaust device for exhausting gas in the vacuum container 1, a pressure adjustment valve 9 serving as one example of a pressure control device for controlling the pressure within the vacuum container 1, and a sample-electrode high-frequency power supply 12 serving as one example of a power supply for supplying a high-frequency power to the sample electrode, as illustrated in the cross-sectional views of FIGS. 1A and 1B, wherein it is characterized in that the distance G between the sample electrode 6 and the counter electrode 3 is set to be sufficiently smaller than the area S of the surface of the sample electrode 6 which is opposed to the counter electrode 3 with the areas being the placement region in which a substrate (more specifically, a silicon substrate) 7 as one example of a sample is to be placed, so as to prevent plasma generated between the sample electrode 6 and the counter electrode 3 from being diffused to the outside of the space between the sample electrode 6 and the counter electrode 3 and also so as to confine the plasma substantially within the space between the sample electrode 6 and the counter electrode 3. Further, in this case, the area of the sample electrode 6 means the area of the substrate placement surface (the area of the exposed portion which is not covered with an insulation member 6B in FIG. 1B) and does not include the areas of the side surface portions of the sample electrode 6. In FIG. 1A, the sample electrode 6 is schematically illustrated as having a rectangular cross-section. One example of the sample electrode 6 has an upper portion having a smaller diameter and having a substrate placement surface at its upper end surface and a lower portion having a protruding portion with a diameter greater than the diameter of the upper portion, and thus is structured to have an upward convex shape, as illustrated in the cross-sectional view of FIG. 1B. In FIG. 1B, 6B designates an insulation member which is made of an insulation material and covers the portion of the upper portion of the sample electrode 6 other than the substrate placement surface. 6C designates an aluminum ring which is grounded and is coupled to supporting columns 10 which will be described later. In FIG. 1B, as an example, the substrate 7 is illustrated as being greater than the substrate placement surface which is the upper end surface of the sample electrode 6 but being smaller than the protruding portion of the lower portion of the sample electrode 6.

That is, referring to FIG. 1A, in the plasma doping apparatus, a predetermined gas (plasma doping gas) is introduced into a gas reservoir 4 provided within the counter electrode 3 within the vacuum container 1 from the gas supply device 2, and then the gas is ejected toward the substrate 7 as an example of the sample placed on the sample electrode 6, through a number of gas ejection holes provided in the counter electrode 3. The counter electrode 3 is placed such that its surface (the lower surface in FIG. 1A) is faced to the surface of the sample electrode 6 (the upper surface in FIG. 1A) substantially in parallel thereto.

Further, the gas supplied from the gas supply device 2 to the vacuum container 1 is exhausted from the vacuum container 1 by the turbo molecular pump 8 as an example of the exhaust device through an exhaust opening 1a, and also the degree of opening of the exhaust opening 1a is adjusted by the pressure adjustment valve 9 as an example of the pressure control device, so that the pressure within the vacuum container 1 is maintained at a predetermined pressure (a plasma doping pressure). Further, the turbo molecular pump 8 and the exhaust opening 1a are placed just below the sample electrode 6, and also the pressure adjustment valve 9 is a liftable valve positioned just below the sample electrode 6 and just above the turbo molecular pump 8. Furthermore, the sample electrode 6 is fixed at a middle portion of the vacuum container 1 with the four insulation supporting columns 10. By supplying a high-frequency electric power with a frequency of 60 MHz to the counter electrode 3 from the counter-electrode high-frequency power supply 11, it is possible to generate capacitive-coupled plasma between the counter electrode 3 and the sample electrode 6. Further, there is provided the sample-electrode high-frequency power supply 12 for supplying a high-frequency electric power with a frequency of 1.6 MHz to the sample electrode 6, and the sample-electrode high-frequency power supply 12 functions as a bias-voltage source which controls the electric potential of the sample electrode 6 such that the substrate 7 as an example of the sample is maintained at a negative potential with respect to the plasma. Instead of using the sample-electrode high-frequency power supply 12, a pulse power supply can also be used to supply a pulse power to the sample electrode 6 to control the potential of the substrate 7. An insulation member 13 is for galvanically isolating the counter electrode 3 from the vacuum container 1 which is grounded. In this manner, by accelerating ions within plasma toward the surface of the substrate 7 as an example of the sample to cause these ions to impinge thereon, it is possible to treat the surface of the substrate 7 as an example of the sample. By using a gas containing diborane or phosphine as the plasma doping gas, it is possible to perform the plasma doping processing.

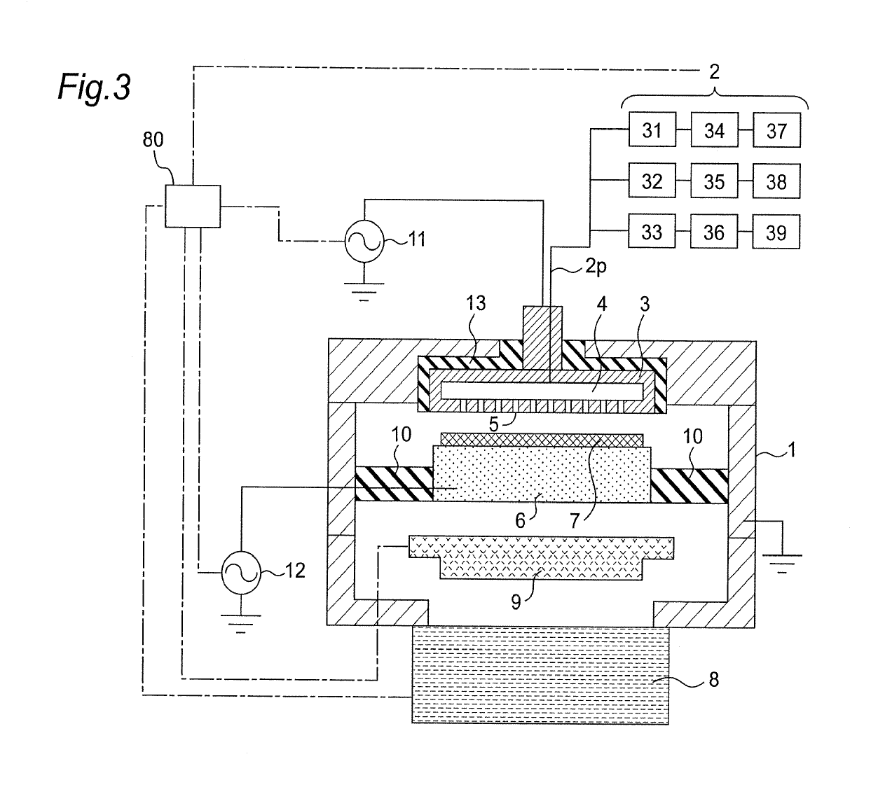

In a case of performing the plasma doping processing, the flow rates of gases each including an impurity material gas are controlled to predetermined values, by flow-rate control devices (mass-flow controllers) (for example, first to third mass-flow controllers 31, 32, and 33 in FIG. 3 which will be described later) which are provided within the gas supply device 2 in FIG. 1A. Generally, a gas prepared by diluting an impurity material gas with helium, such as a gas prepared by diluting diborane (B₂H₆) to 0.5% with helium (He), is used as the impurity material gas, and the flow rate of this gas is controlled by the first mass-flow controller (for example, the first mass-flow controller 31 in FIG. 3 which will be described later). Further, the flow rate of helium is controlled by the second mass-flow controller (e.g., the second mass-flow controller 32 in FIG. 3 which will be described later). Further, these gases controlled in flow rate by the first and second mass-flow controllers are mixed with each other in the gas supply device 2, and thereafter, the mixed gas is introduced into the gas reservoir 4 through a pipe 2p. The impurity material gas which has been adjusted to have a predetermined concentration is supplied from the gas reservoir 4 to the gap between the counter electrode 3 and the sample electrode 6 within the vacuum container 1, through the number of gas ejection holes 5.

Further, in FIG. 1A, 80 designates a control device for controlling plasma doping processing, and this control device 80 controls the respective operations of the gas supply device 2, the turbo molecular pump 8, the pressure adjustment valve 9, the counter-electrode high-frequency power supply 11, and the sample-electrode high-frequency power supply 12 for performing the predetermined plasma doping processing.

As an actual example, the substrate 7 used herein is a silicon substrate with a circular shape (having a notch at a portion thereof) and a diameter of 300 mm. Further, there will be described in the following, as an example, plasma doping processing in the case where the distance G between the sample electrode 6 and the counter electrode 3 is set to 25 mm.

In performing plasma doping using the aforementioned plasma processing apparatus, at first, the inner walls of the vacuum container 1 including the surface of the counter electrode 3 are cleaned using water and an organic solvent.

Next, a substrate 7 is placed on the sample electrode 6.

Next, a high-frequency electric power of 1600 W is supplied from the counter-electrode high-frequency power supply 11 to the counter electrode 3, while the temperature of the sample electrode 6 is maintained at, for example, 25 C°. B₂H₆ gas diluted with He, and He gas, for example, are supplied at flow rates of 5 sccm and 100 sccm, respectively, from the gas supply device 2 into the vacuum container 1, and also, the pressure within the vacuum container 1 is maintained at 0.8 Pa by the pressure adjustment valve 9, to generate plasma between the counter electrode 3 and the substrate 7 on the sample electrode 6 within the vacuum container 1. Also, a high-frequency electric power of 140 W is supplied from the sample-electrode high-frequency power supply 12 to the sample electrode 6 for 50 seconds to cause boron ions within the plasma to impinge on the surface of the substrate 7, thus implanting boron to the vicinity of the surface of the substrate 7. Then, the substrate 7 is taken out from the vacuum container 1 and activated, and thereafter, the surface resistance (a value relating to the amount of dose) is measured.

Under the same conditions, plasma doping processing is successively applied to the substrates 7. As a result, first several substrates exhibit decreasing surface resistance after activation, and the substrates subsequent thereto exhibit a substantially constant surface resistance, as illustrated by a curve “a” in FIG. 2.

Further, after the surface resistance reaches a substantially constant value, the surface resistance is varied within an extremely small width.

For comparison, the same processing is conducted using an inductively-coupled plasma source as in the prior-art example (in the prior-art example, the distance between the quartz plate which is dielectric and the electrode is in the range of 200 mm to 300 mm). As a result, first several tens of substrates exhibit moderately-decreasing surface resistance, and the substrates subsequent thereto exhibit surface resistance asymptotically approaching a constant value, as illustrated by a curve “b” in FIG. 2.

Further, in the prior-art example, after the surface resistance substantially reach a constant value, the surface resistance is varied within a relatively large variation width, which is several times the variation width of the present first embodiment.

Hereinafter, there will be described reasons for the fact that the aforementioned difference is observed.

In the prior-art example, during successively performing the plasma doping processing just after the cleaning of the inner wall of the vacuum container 1, a thin film containing boron is gradually deposited on the inner wall surface of the vacuum container 1. It is considered that this phenomenon occurs since boron-based radicals (neutral particles) produced within the plasma are adsorbed to the inner wall surface of the vacuum container, and also boron-based ions are accelerated by the potential difference between the plasma potential (=approximately 10 to 40 V) and the potential of the inner wall of the vacuum container (usually, since the inner wall of the vacuum container is dielectric, a floating potential=approximately 5 to 20 V) and then impinge on the inner wall surface of the vacuum container, so that a thin film containing boron is grown thereon due to thermal energy or ion impingement energy. It is considered that, along with the increase in the thickness of this deposited film, the probability of adsorption of boron-based radicals to the inner wall surface of the vacuum container is gradually decreased, and therefore, the density of boron-based radicals within the plasma is gradually increased, in the case of using B₂H₆ as a doping material gas. Further, ions within the plasma are accelerated by the aforementioned potential difference and then impinge on the boron-based thin film deposited on the inner wall surface of the vacuum container, which causes sputtering, thereby gradually increasing the amount of particles containing boron which are supplied to the plasma. Consequently, the amount of dose is gradually increased, which gradually decreases the surface resistance after activation. Further, the temperature of the inner wall surface of the vacuum container is varied along with the generation of plasma or the stoppage thereof, which varies the probability of adsorption of boron-based radicals to the inner wall surface, thereby causing the surface resistance after activation to be largely varied.

On the other hand, in the present first embodiment, the distance G between the sample electrode 6 and the counter electrode 3 is as small as 25 mm as compared with the area of the sample electrode 6 in which a wafer with a diameter of 300 mm as an example of the substrate 7 is placed, so that so-called narrow-gap discharge is caused. Further, the processing is performed while the gas is ejected toward the surface of the substrate 7 through the gas ejection holes 5 provided in the counter electrode 3. In this case, the surface condition of the inner wall surface of the vacuum container 1 (except the surface of the counter electrode 3) exerts significantly small influence on the density of boron-based radicals and the density of boron ions within the plasma. This is mainly for the following four reasons.

(1) Due to the narrow-gap discharge, the plasma is mainly generated only between the counter electrode 3 and the substrate 7, and therefore, boron-based radicals are very unlikely to be adsorbed to the inner wall surface of the vacuum container 1 (except the surface of the counter electrode 3), so that a thin film containing boron is less likely to be deposited thereon.

(2) The area of the inner wall surface of the vacuum container 1 (except the surface of the counter electrode 3) relative to the substrate 7 is smaller than that of the prior-art example, which reduces the influence of the inner wall surface of the vacuum container 1.

(3) Due to the application of the high-frequency electric power to the counter electrode 3, a self-bias voltage is generated at the surface of the counter electrode 3, and therefore, boron-based radicals are very unlikely to be adsorbed thereto, so that the condition of the surface of the counter electrode 3 is hardly changed even when the doping processing is successively performed.

(4) The gas is flowed along the surface of the substrate 7 in a single direction from the center of the substrate 7 to the periphery thereof, which attenuates the influence of the inner wall surface of the vacuum container 1 on the substrate 7.

Further, the present inventors determine a preferable range for the distance between the sample electrode 6 and the counter electrode 3. Assuming that the area of the surface of the substrate 7 (the surface which is faced to the counter electrode 3 or the surface of the sample electrode 6 which is faced to the counter electrode 3 and also the placement region on which the substrate 7 is to be placed) is S, in the case where the substrate 7 has a circular shape, the radius thereof is (S/π)^{-1/2}. Assuming that the distance between the sample electrode 6 and the counter electrode 3 is G, under a condition where the following equation (3) holds, namely under a condition where the inter-electrode distance G falls within the range of 0.1 time to 0.4 time the radius of the substrate 7, a preferable impurity concentration reproducibility is obtained.

0.1\sqrt{(S/π)} [symbol] G [symbol] 0.4\sqrt{(S/π)} (3)

When the inter-electrode distance G is excessively small (smaller than 0.1 time the radius), plasma could not be generated within a pressure range suitable for performing the plasma doping (equal to or less than 3 Pa). On the contrary, when the inter-electrode distance G is excessively large (larger than 0.4 time the radius), several tens of substrates were required until the surface resistance after activation is stabilized just after wet cleaning, as in the prior-art example. Further, after the surface resistance is substantially stabilized, the surface resistance is varied within a large variation width.

As described above, generating the narrow-gap discharge through the application of the high-frequency electric power to the counter electrode 3 using the high-frequency power supply 11 is extremely important in ensuring the processing reproducibility. This is a particularly prominent phenomenon in plasma doping. In a case where the variation in etching property due to the deposition of a carbon-fluoride-based thin film on the inner wall of the vacuum container is problematic in applying dry etching to an insulation film, narrow-gap discharge may be utilized, wherein the concentration of carbon-fluoride-based gas within mixed gas introduced into the vacuum container is about several percentages, and the influence of the deposited film is relatively small. On the other hand, in the case of the plasma doping, the concentration of impurity material gas within inert gas introduced into the vacuum container is 1% or less (0.1% or less, particularly in a case where it is desired to control the amount of dose with higher accuracy), which causes the influence of the deposited film to be relatively large. In the case where the concentration of impurity material gas within inert gas exceeds 1%, it is impossible to provide a so-called self-regulation effect, thereby inducing malfunction that the amount of dose cannot be controlled accurately. Accordingly, the concentration of impurity material gas within inert gas is set to be 1% or less. It is necessary that the concentration of impurity material gas within inert gas introduced into the vacuum container be equal to or more than 0.001%. If it is smaller than 0.001%, processing should be performed for an extremely long time to attain a desired amount of dose.

Further, the use of the present invention offers the advantage of improvement in the accuracy of controlling the amount of dose, dose monitoring utilizing in-situ monitoring techniques such as emission spectroscopy and mass spectrometry, and the like. This is because of the following reason. That is, it is known that the saturation amount of dose in the so-called self-regulation phenomenon depends on the concentration of impurity material gas within mixed gas introduced into the vacuum container, wherein the self-regulation phenomenon is a phenomenon that, in processing a single substrate, the amount of dose is saturated along with the elapse of processing time. According to the present invention, it is possible to obtain relatively easily measurement values strongly relating to particles such as ions and radicals generated by dissociation or electrolytic dissociation of impurity material gas within plasma through in-situ monitoring, regardless of the condition of the inner wall of the vacuum container.

Further, in the plasma doping apparatus described in the Patent Document 4, the counter electrode (anode) provided opposite to the sample is maintained at a ground electric potential, which causes a thin film containing boron to be deposited on the counter electrode, when plasma doping processing is successively performed. Further, the Patent Document 4 only describes that the distance (gap) between the counter electrode (anode) and the sample electrode (cathode) “can be adjusted with respect to different voltages”.

In the aforementioned first embodiment of the present invention, there have been exemplified only portions of various variations of the shape of the vacuum container 1, the structure and placement of the electrodes 3 and 6, and the like, within the applicable scope of the present invention. It goes without saying that the present invention can be implemented in various variations, as well as the aforementioned examples.

Further, there has been exemplified a case where the high-frequency electric power with a frequency of 60 MHz is supplied to the counter electrode 3, and where the high-frequency electric power with a frequency of 1.6 MHz is supplied to the sample electrode 6, these frequencies are merely illustrative. A preferable frequency of the high-frequency electric power supplied to the counter electrode 3 is substantially within the range of 10 MHz to 100 MHz. If the frequency of the high-frequency electric power supplied to the counter electrode 3 is lower than 10 MHz, it is impossible to provide a sufficient plasma density. On the contrary, if the frequency of the high-frequency electric power supplied to the counter electrode 3 is higher than 100 MHz, it is impossible to provide a sufficient self-bias voltage, which tends to cause a thin film containing impurities to be deposited on the surface of the counter electrode 3.

A preferable frequency of the high-frequency electric power supplied to the sample electrode 6 is substantially within the range of 300 kHz to 20 MHz. If the frequency of the high-frequency electric power supplied to the sample electrode 6 is lower than 300 kHz, it is impossible to attain high-frequency matching easily. On the contrary, if the frequency of the high-frequency electric power supplied to the sample electrode 6 is higher than 20 MHz, this will tend to induce an in-plain distribution in the voltage applied to the sample electrode 6, thereby degrading the uniformity of doping processing.

Further, the surface of the counter electrode 3 can be made of silicon or a silicon oxide, which can prevent the implantation of undesirable impurities into the surface of a silicon substrate as an example of the substrate 7.

Further, in the case where the substrate 7 is a semiconductor substrate made of silicon, the substrate 7 can be utilized in fabrication of fine transistors, by using arsenic, phosphorus, or boron as the impurities. Also, the substrate 7 may be made of a compound semiconductor. Aluminum or antimony can be used as the impurities.

Further, a known heater and a known cooling device can be incorporated to respectively control the temperature of the inner wall of the vacuum container 1 and the temperatures of the counter electrode 3 and the sample electrode 6, which enables controlling, with higher accuracy, the probability of adsorption of impurity radicals to the inner wall of the vacuum container 1, the counter electrode 3, and the surface of the substrate 7, thereby further increasing the reproducibility.

Further, while there has been exemplified a case where a mixed gas prepared by diluting B₂H₆ with He is used as plasma doping gas to be introduced into the vacuum container 1, generally, it is also possible to use a mixed gas prepared by diluting an impurity material gas with a rare gas. As an impurity material gas, it is possible to use BxHy (x and y are positive integers) or PxHy (x and y are positive integers). These gases have the advantage of containing, as impurities, only H which will have less influence on the substrate even if it is intruded into the substrate, in addition to B or P. It is also possible to use other gasses containing B, such as BF₃, BCl₃, or BBr₃. Also, it is possible to use other gasses containing P, such as PF₃, PF_{S}, PCl₃, PCl₅, or POCl₃. Further, He, Ne, Ar, Kr, Xe, or the like can be used as the rare gas, but He is most preferable. This is for the following reason. The use of He can prevent the implantation of undesirable impurities into the surfaces of samples and also can realize a plasma doping method with excellent reproducibility while realizing both accurate control of the amount of dose and a low sputtering property. By using a mixed gas prepared by diluting an impurity material gas with a rare gas, it is possible to significantly reduce the change in the amount of dose caused by the film containing impurities such as boron which has been formed on the chamber inner wall. This enables controlling the distribution of the amount of dose with higher accuracy, by controlling the gas ejection distribution. This makes it easier to ensure preferable in-plain uniformity of the amount of dose. Ne is the most preferable rare gas next to He. Ne has the advantage of easily causing discharge at a low pressure, while having the drawback of having a sputtering rate slightly higher than He.

It should be noted that the present invention is not limited to the first embodiment and can be implemented in various modes.

For example, while, in the first embodiment, there has been exemplified a case where B₂H₆ gas diluted with He, and He gas are supplied from the gas supply device 2 at flow rates of 5 sccm and 100 sccm, respectively, and the high-frequency electric power of 1600 W is supplied to the counter electrode 3 from the counter-electrode high-frequency power supply 11 while the pressure within the vacuum container 1 is maintained at 0.8 Pa by the pressure adjustment value 9, thus generating plasma between the counter electrode 3 and the substrate 7 on the sample electrode 6 within the vacuum container 1, there are cases where it is difficult to generate plasma at a low pressure in a state where the partial pressure of He gas is high. In this case, it is effective to appropriately employ the following methods as modifications of the first embodiment of the present invention.

A first method is a method which changes the pressure. At first, a high-frequency electric power is supplied to the counter electrode 3 from the counter-electrode high-frequency power supply 11, while the pressure within the vacuum container 1 is maintained, through the pressure adjustment valve 9, at a plasma-generating pressure which is equal to or higher than 1 Pa (typically, 10 Pa) and higher than the plasma doping pressure, to generate plasma between the counter electrode 3 and the substrate 7 on the sample electrode 6 within the vacuum container 1. At this time, the sample electrode 6 is not supplied with a high-frequency electric power from the sample-electrode high-frequency power supply 12. After the plasma is generated, the pressure within the vacuum container 1 is gradually reduced to the plasma doping pressure which is equal to or lower than 1 Pa (typically, 0.8 Pa), by adjusting the pressure adjustment valve 9. A similar procedure can be possibly used in the case of using a so-called high-density plasma source such as an ECR (electron cyclotron resonance plasma source) or an ICP (inductively coupled plasma source). However, in the structure of the apparatus according to the modification of the first embodiment of the present invention, the volume of plasma is significantly smaller than that in the case of using a high-density plasma source, and accordingly, it is necessary to decrease the pressure more slowly by the pressure adjustment valve 9 in order to prevent the generated plasma from being lost. However, if the pressure is decreased excessively slowly, this will extend the total processing time and also may cause contamination on the substrate 7. Accordingly, it is preferable to decrease the pressure by taking about 3 to 15 seconds using the pressure adjustment valve 9. After the pressure within the vacuum container 1 is decreased to the plasma doping pressure, a high-frequency electric power is supplied to the sample electrode 6 from the sample-electrode high-frequency power supply 12.

A second method is a method which changes the types of gases. As illustrated in FIG. 3, the gas supply device 2 is constituted by, for example, the first to third mass-flow controllers 31, 32, and 33 which are controlled and operated by the control device 80, first to third valves 34, 35, and 36 which are controlled and operated by the control device 80, and first to third bottles 37, 38, and 39. The first bottle 37 stores B₂H₆ gas diluted with He, the second bottle 38 stores He gas, and the third bottle 39 stores Ne gas. Then, at first, Ne gas, which is an example of a plasma-generating gas which can cause discharge at a lower pressure more easily than He, is supplied from the third bottle 39 into the vacuum container 1, through the third valve 38, the third mass-flow controller 33, and the pipe 2p, by opening the third valve 38 while closing the first and second valves 34 and 35. The flow rate of Ne gas from the third bottle 39 is maintained at a constant value by the third mass-flow controller 33. At this time, the flow rate of Ne gas is set to be substantially the same as the gas flow rate at the later step of supplying the high-frequency electric power to the sample electrode 6. The high-frequency electric power is supplied from the counter-electrode high-frequency power supply 11 to the counter electrode 3 while the pressure within the vacuum container 1 is maintained at 0.8 Pa by the pressure adjustment valve 9, to generate plasma between the counter electrode 3 and the substrate 7 on the sample electrode 6 within the vacuum container 1. At this time, the sample electrode 6 is not supplied with the high-frequency electric power. After the plasma is generated, the gas supplied into the vacuum container 1 through the first and second valves 34 and 35, the first and second mass-flow controllers 31 and 32, and the pipe 2p from the first and second bottles 37 and 38 is changed to the mixed gas constituted by He and B₂H₆ gas, by opening the first and second valves 34 and 35 while closing the third valve 38. The flow rates of these gases are maintained at constant values by the first and second mass-flow controllers 31 and 32. After the types of gases are changed, the high-frequency electric power is supplied to the sample electrode 6 from the sample-electrode high-frequency power supply 12. A similar procedure can be possibly used in the case of using a so-called high-density plasma source such as an ECR (electron cyclotron resonance plasma source) or an ICP (inductively-coupled plasma source). However, in the structure of the apparatus according to the present invention, the volume of plasma is significantly smaller than that in the case of using the high-density plasma source, and accordingly, it is preferable to change the type of gas more slowly in order to prevent the generated plasma from being lost. However, if the type of gas is changed excessively slowly, it will extend the total processing time and also may cause contamination on the substrate 7. Accordingly, it is preferable to change the type of gas by taking about 3 to 15 seconds. In order to change the type of gas slowly, the set flow-rate values of the first and second mass-flow controllers 31 and 32 are set to zero or an extremely-small value (10 sccm or less) at the moment of opening the first and second valves 34 and 35, and then these set flow-rate values are controlled such that the flow rates are gradually increased. Further, after the first and second valves 34 and 35 are opened, the set flow-rate value of the third mass-flow controller 33 is gradually reduced while the third valve 33 is kept open, and after the set flow-rate value of the third mass-flow controller 33 reaches zero or an extremely-small value (10 sccm or less), the third valve 36 is closed.

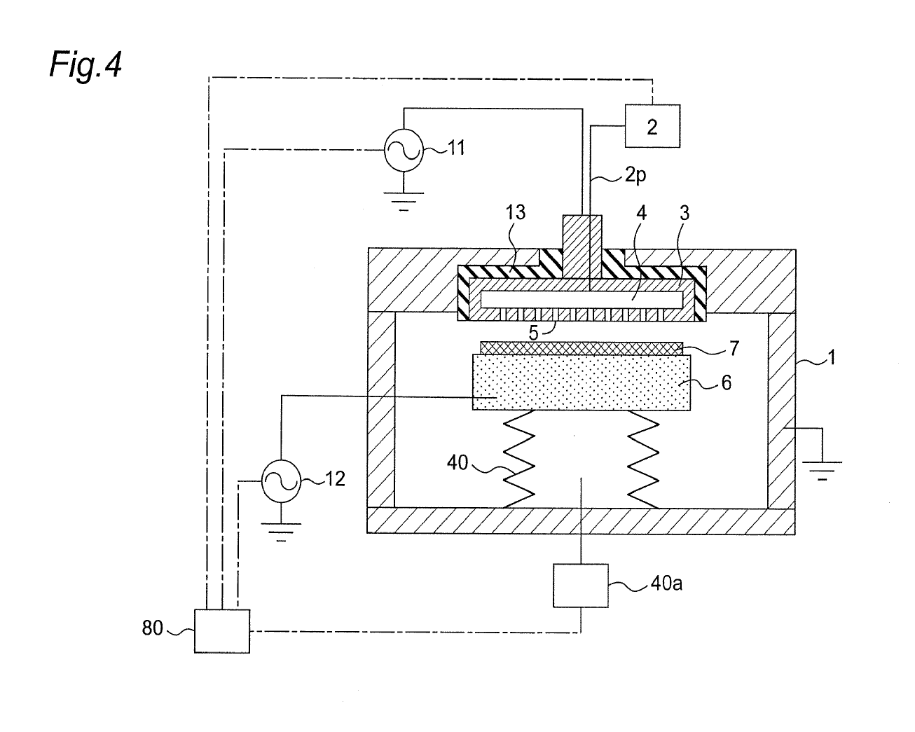

A third method is a method which changes the distance G between the sample electrode 6 and the counter electrode 3. As another modification of the first embodiment, in order to move the sample electrode 6 and the counter electrode 3 relative to each other to control the distance G between the sample electrode 6 and the counter electrode 3, for example, as illustrated in FIG. 4, there is provided a bellows 40 as an example of a distance-adjustment driving device (such as a sample-electrode lifting/lowering driving device) between the bottom surface of the vacuum container 1 and the sample electrode 6 within the vacuum container 1 (or as an example of a distance-adjustment driving device (such as a counter-electrode lifting/lowering driving device) between the upper surface of the vacuum container 1 and the counter electrode 3 within the vacuum container 1, in the case of lifting or lowering the counter electrode). Further, there is provided a fluid supply device 40a for supplying, to the bellows 40, a fluid for expanding or contracting the bellows 40, such that the sample electrode 6 (or the counter electrode 3) can be lifted or lowered freely within the vacuum container 1 through the bellows 40 by driving the fluid supply device 40a through the operation control by the control device 80. In this case, the pressure adjustment valve 9 and the pump 8 are provided on a side surface of the vacuum container 1 (not illustrated). In the apparatus having such a structure, at first, the sample electrode 6 is lowered (or the counter electrode 3 is lifted), by driving the fluid supply device 40a, to set the distance G to the plasma generating distance of, for example, 80 mm, which is greater than the plasma-doping distance. In this state, B₂H₆ gas diluted with He, and He gas are supplied from the gas supply device 2 to the vacuum container 1, and the high-frequency electric power is supplied to the counter electrode 3 from the counter-electrode high-frequency power supply 11 while the pressure within the vacuum container 1 is maintained at 0.8 Pa by the pressure adjustment value 9, to generate plasma between the counter electrode 3 and the substrate 7 on the sample electrode 6 within the vacuum container 1. At this time, the sample electrode 6 is not supplied with the high-frequency electric power. After the plasma is generated, the sample electrode 6 is lifted (or the counter electrode 3 is lowered), by driving the fluid supply device 40a, to change the distance G to 25 mm. The generation of the plasma may be automatically detected by detecting plasma light emission with a detector, through a window provided in the vacuum container 1. In this case, the fluid supply device 40a may be driven on the basis of detection signals from the detector. More simply, a time period sufficient to generate the plasma may be preliminarily set, and after the elapse of the plasma generating preset time period, the fluid supply device 40a may be driven on the assumption that the plasma has been generated. After the distance G is set to be 25 mm, the driving of the fluid supply device 40a is stopped, and the high-frequency electric power is supplied to the sample electrode 6 from the sample-electrode high-frequency power supply 12. If the distance G is changed excessively abruptly, the generated plasma may be lost. On the contrary, if the distance G is changed excessively slowly, this will extend the total processing time and also may cause contamination on the substrate 7. Accordingly, it is preferable to change the distance G by taking about 3 to 15 seconds. While, in the present modification, there has been exemplified a case where the distance G is set to 80 mm in the step of generating the plasma at first, it is preferable to generate the plasma in a state where the following equation (4) is satisfied.

$$0.4 \sqrt{\frac{S}{π}} < G < \sqrt{\frac{S}{π}} \qquad ( 4 )$$

If the distance G is excessively small (smaller than 0.4 time the radius), plasma may not be generated. On the contrary, if the distance G is excessively large (larger than 1.0 time the radius), this will excessively increase the volume of the vacuum container 1, resulting in insufficient pump exhaust ability.

Also, two or more methods out of the aforementioned three methods may be combined.

Note that, in the case of using an ICP (inductively-coupled plasma source), in order to reduce the number of substrates required until the surface resistance after activation is stabilized from just after the wet cleaning is finished, it is effective to perform processing in a state where the distance G between the sample electrode 6 and the dielectric window facing to the sample electrode 6 satisfies the following equation (5).

$$0.1 \sqrt{\frac{S}{π}} < G < 0.4 \sqrt{\frac{S}{π}} \qquad ( 5 )$$

Also, in the aforementioned modification, the bellows 40 as an example of the sample-electrode lifting/lowering driving device may be provided between the bottom surface of the vacuum container 1 and the sample electrode 6 within the vacuum container 1, and also, the bellows 40 as an example of the counter-electrode lifting/lowering driving device may be provided between the upper surface of the vacuum container 1 and the counter electrode 3 within the vacuum container 1 for lifting and lowering the counter electrode. Thus, both the sample electrode 6 and the counter electrode 3 may be moved to move the sample electrode 6 and the counter electrode 3 relative to each other, in order to control the distance G between the sample electrode 6 and the counter electrode 3.

Also, in the case where the present invention is applied to an ECR (electron cyclotron resonance plasma source) or an ICP (inductively-coupled plasma source), the distance between the counter electrode and a dielectric plate or a surface including gas ejection holes may be set as G, instead of setting the distance between the sample electrode and the aforementioned counter electrode as G.

Further, while, in the present invention, the distance G has been described as being the distance between the electrodes, it is necessary that the distance G be defined as the distance between the substrate and the electrode in a strict sense. However, the substrate is significantly smaller than the distance, and accordingly, there is no problem in describing the distance G as the distance between the electrodes without taking into consideration the thickness of the substrate in the embodiments and examples.

By properly combining the arbitrary embodiments of the aforementioned various embodiments, the effects possessed by the embodiments can be produced.

### INDUSTRIAL APPLICABILITY

According to the present invention, there are provided a plasma doping method and apparatus having excellent reproducibility of the concentration of impurity implanted into the surfaces of samples. Accordingly, the present invention can be applied to fabrication of thin-film transistors for use in liquid crystals and the like, including impurity doping processing for semiconductor devices.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1-20. (canceled)

21. A plasma doping method comprising:
placing a substrate on a first electrode within a vacuum chamber;
supplying a plasma generating gas which causes discharge at a lower pressure more easily than a dilution gas used for diluting an impurity material gas in a plasma doping gas into the vacuum chamber, supplying a high-frequency electric power to a second electrode which is placed opposite the first electrode while a pressure within the vacuum chamber is maintained at a predetermined pressure, generating plasma between a surface of the substrate and a surface of the second electrode within the vacuum chamber, and switching a gas supplied into the vacuum chamber to a plasma doping gas after the plasma is generated;
supplying an electric power to the first electrode, while supplying the plasma doping gas into the vacuum chamber, exhausting gas from the vacuum chamber, and controlling the pressure within the vacuum chamber to the predetermined pressure, and generating plasma between the surface of the substrate and the surface of the second electrode within the vacuum chamber;
supplying the high-frequency electric power to the second electrode; and
performing plasma doping processing to implant impurities into the surface of the substrate, in a state satisfying,
0.1\sqrt{(S/π)} [symbol] G [symbol] 0.4\sqrt{(S/π)}
where S is an area of the surface of the substrate which is facing to the second electrode, and
G is a distance between the first electrode and the second electrode.

22. The plasma doping method as claimed in claim 21, wherein a concentration of impurity material gas within the plasma doping gas introduced into the vacuum chamber is equal to or less than 1%.

23. The plasma doping method as claimed in claim 21, wherein the plasma doping gas introduced into the vacuum chamber is a mixed gas prepared by diluting the impurity material gas with a rare gas.

24. The plasma doping method as claimed in claim 23, wherein the rare gas is He.

25. The plasma doping method as claimed in claim 21, wherein the impurity material gas within the plasma doping gas is made of boron and hydrogen.

26. The plasma doping method as claimed in claim 21, wherein the impurity material gas within the plasma doping gas is made of phosphor and hydrogen.

27. The plasma doping method as claimed in claim 21, wherein the plasma doping processing is performed while the gas is ejected toward the surface of the substrate through gas ejection holes provided in the second electrode.

28. The plasma doping method as claimed in claim 21, wherein the plasma doping processing is performed in a state where the surface of the second electrode is made of silicon or a silicon oxide.

29. The plasma doping method as claimed in claim 21, wherein the plasma doping processing is performed in a state where the substrate is a semiconductor substrate made of silicon.

30. The plasma doping method as claimed in claim 21, wherein impurities within the impurity material gas contained in the plasma doping gas used when the plasma doping processing is performed to implant the impurities into the surface of the substrate is arsenic, phosphorus, or boron.

31. A plasma doping method comprising:
placing a substrate on a first electrode within a vacuum chamber;
supplying a high-frequency electric power is supplied to a second electrode which is placed opposite the first electrode while a pressure within the vacuum chamber is maintained at a plasma generating pressure which is higher than a predetermined pressure, to generate plasma between a surface of the substrate and a surface of the second electrode within the vacuum chamber, gradually decreasing the pressure within the vacuum chamber to the predetermined pressure after the plasma is generated;
supplying an electric power to the first electrode, while supplying the plasma doping gas into the vacuum chamber, exhausting gas from the vacuum chamber, and controlling the pressure within the vacuum chamber to the predetermined pressure, and generating plasma between the surface of the substrate and the surface of the second electrode within the vacuum chamber;
supplying the high-frequency electric power to the second electrode; and
performing plasma doping processing to implant impurities into the surface of the substrate, in a state satisfying,
0.1\sqrt{(S/π)} [symbol] G [symbol] 0.4\sqrt{(S/π)}
where S is an area of the surface of the substrate which is facing to the second electrode, and
G is a distance between the first electrode and the second electrode.

32. A plasma doping method comprising:
placing a substrate on a first electrode within a vacuum chamber;
supplying an electric power to the first electrode, while supplying a plasma doping gas into the vacuum chamber, exhausting gas from the vacuum chamber, and controlling a pressure within the vacuum chamber to a predetermined pressure, and generating plasma between a surface of the substrate and a surface of the second electrode within the vacuum chamber;
supplying a high-frequency electric power to the second electrode which is placed opposite the first electrode; and
performing plasma doping processing to implant impurities into the surface of the substrate, in a state satisfying following equation,
0.1\sqrt{(S/π)} [symbol] G [symbol] 0.4\sqrt{(S/π)}
where S is an area of the surface of the substrate which is facing to the second electrode, and
G is a distance between the first electrode and the second electrode,
wherein, after the substrate is placed on the first electrode within the vacuum chamber and before the electric power is supplied to the first electrode,
relatively moving the first electrode and the second electrode to separate the first electrode from the second electrode such that the distance G between the first electrode and the second electrode is larger than a range defined by the equation, and in this state, supplying the high-frequency electric power to the second electrode while a plasma doping gas is supplied into the vacuum chamber, gas is exhausted from the vacuum chamber, and an inside of the vacuum chamber is controlled to the predetermined pressure, generating plasma between the surface of the substrate and the surface of the second electrode within the vacuum chamber, relatively moving the first electrode and the second electrode after the plasma is generated to restore a state where the distance G satisfies the equation, and thereafter, supplying the electric power to the first electrode.
